(19) United States
(12) Patent Application Publication
(10) Pub. No.: US 2014/0038440 A1
(43) Pub. Date: Feb. 6, 2014

(54) ELECTRICAL CONNECTOR WITH CAP FOR COVERING PARTIAL RECEIVING HOLES

(71) Applicant: HON HAI PRECISION INDUSTRY CO., LTD., New Taipei (TW)

(72) Inventor: SHUO-HSIU HSU, New Taipei (TW)

(73) Assignee: HON HAI PRECISION INDUSTRY CO., LTD., New Taipei (TW)

(21) Appl. No.: 13/958,639

(22) Filed: Aug. 5, 2013

(30) Foreign Application Priority Data
Aug. 3, 2012 (TW) 101127967

(51) Int. Cl. H05K 7/10

(52) U.S. Cl. CPC H05K 7/10
USPC 439/135

(57) ABSTRACT

An electrical connector includes an insulating housing having a bottom wall defining an upper surface, a lower surface opposite to the upper surface and a number of receiving holes running through the upper and lower surfaces; a number of contacts received in the receiving holes wherein the number of the contacts is less than the number of the receiving holes, partial receiving holes are vacant; and a cap assembled on the upper surface of the bottom wall and covering the vacant receiving holes to form a non-conductive portion.

### BACKGROUND OF THE INVENTION

1. Field of the Invention

The present disclosure relates to an electrical connector for connecting an IC package with a printed circuit board, and particularly to an electrical connector having a cap covering on a number of receiving holes to form a non-conductive portion.

2. Description of Related Art

Various electrical connector are widely used in a part of computer connectors. An electrical connector for connecting a Central Processing Unit (CPU) with terminals to a printed circuit board (PCB) typically comprises an insulating housing having a plurality of receiving holes and a plurality of contacts received in the receiving holes. The arrangement of the contacts is relative to the terminals on the CPU. The insulating housing defines an integrated non-conductive portion having no contacts received therein corresponding to the area of the CPU having no terminals. However, with the upgrading of the CPU, the new generation CPU is always different from the last generation CPU on the number or arrangement of the terminals. And the difference therebetween changes the arrangement of the contacts and the position of the non-conductive portion of the corresponding electrical connector, thus a new mold must be needed for manufacturing the electrical connector which results in much more cost.

Another aspect, with the development of technology, more and more contacts are needed in an electrical connector, while the insulating housing retaining the contacts becomes bigger and bigger which result in many difficulties in manufacturing, such as the strength of the insulating housing is not enough and deformation easily. Therefore, an insulating housing having a plurality of housing segments is provided where the housing segments are manufactured separately and then assembled together to form the insulating housing. However, if non-conductive portions of the housing segments are not rotationally symmetric, different molds are needed for manufacturing the housing segments which results in much more cost.

In view of the above, an improved electrical connector is desired to overcome the problems mentioned above.

### SUMMARY OF THE INVENTION

Accordingly, an object of the present disclosure is to provide an electrical connector in which a non-conductive portion can be formed easily for manufacturing different insulating housings.

According to one aspect of the present disclosure, an electrical connector is provided for electrically connecting a Central Processing Unit (CPU) with a printed circuit board (PCB). The electrical connector comprises an insulating housing having a bottom wall defining an upper surface, a lower surface opposite to the upper surface and a plurality of receiving holes running through the upper and lower surfaces; a plurality of contacts received in the receiving holes wherein the number of the contacts is less than the number of the receiving holes, partial receiving holes are vacant; and at least one cap assembled on the upper surface of the bottom wall and covering the vacant receiving holes to form a non-conductive portion.

Other objects, advantages and novel features of the disclosure will become more apparent from the following detailed description when taken in conjunction with the accompanying drawings, in which:

### BRIEF DESCRIPTION OF THE DRAWINGS

FIG. 1 is an assembled, perspective view of an electrical connector in accordance with a preferred embodiment of the present disclosure;

FIG. 2 is an exploded, perspective view of the electrical connector shown in FIG. 1;

FIG. 3 is a partial enlarged view of the electrical connector shown in circle A of FIG. 2;

FIG. 4 is a partial enlarged view of the electrical connector shown in circle B of FIG. 2;

FIG. 5 is another view of a cap shown in FIG. 4;

FIG. 6 is a view similar with FIG. 3, and show a bottom side, wherein a first type of the cap is assembled on the insulating housing; and

FIG. 7 is a view similar with FIG. 4, and show a bottom side, wherein a second type of the cap is assembled on the insulating housing.

### DETAILED DESCRIPTION OF THE INVENTION

Reference will now be made to the drawings to describe the present disclosure in detail.

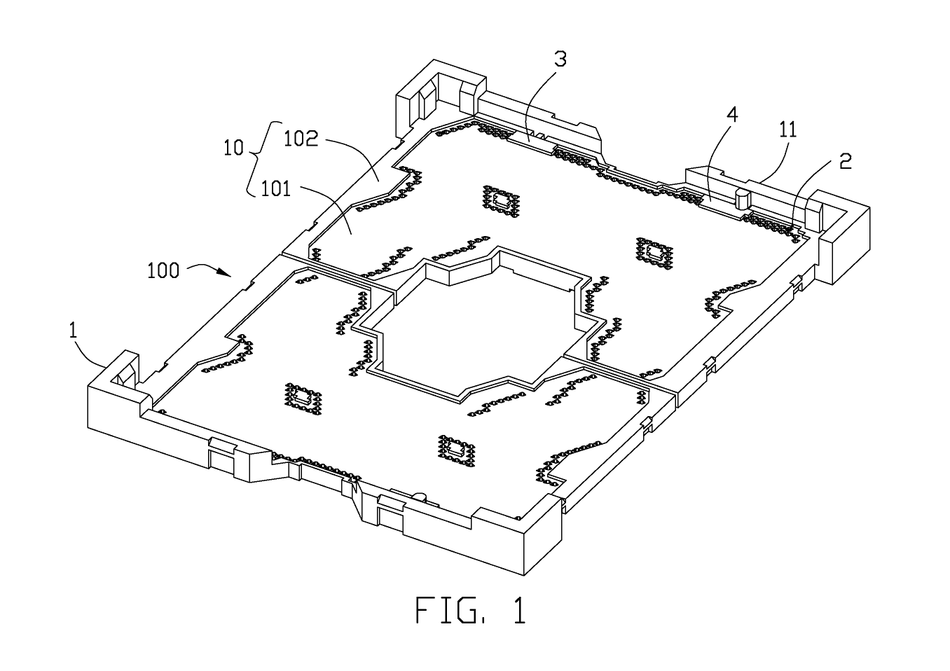

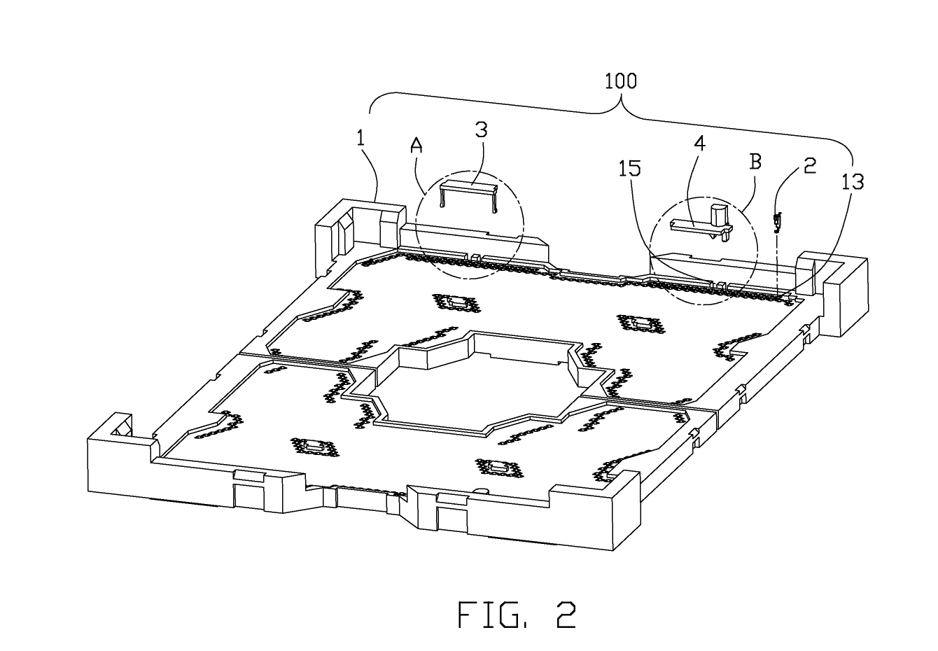

Referring to FIG. 1 and FIG. 2, an electrical connector 100 for electrically connecting an IC package (not shown) and a printed circuit board (not shown), comprises an insulating housing 1, a plurality of contacts 2 retained in the insulating housing 1, and a plurality of caps 3, 4 assembled on the insulating housing 1.

The insulating housing 1 comprises a bottom wall 10 and a plurality of side walls 11 extending upwardly from the bottom wall 10. The bottom wall 10 together with the side walls 11 defines a cavity for receiving the IC package. The bottom wall 10 comprises an upper surface, a lower surface opposite to the upper surface, and a plurality of receiving holes 13 running through the upper and lower surfaces. The bottom wall 10 comprises a conductive area 101 having the contacts 2 retained therein and a supporting area 102 having no receiving holes 13 therethrough for supporting the IC package, and wherein the conductive area 101 is lower than the supporting area 102. The contacts 2 are received in the receiving holes 13. The number of the contacts 2 is less than the number of the receiving holes 13, thus partial receiving holes 13 are vacant receiving holes having no contacts 2 received therein.

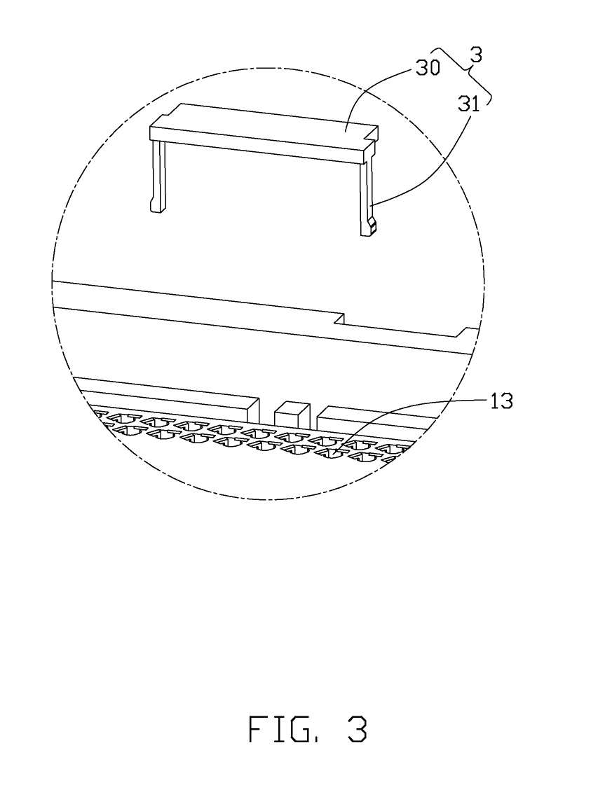

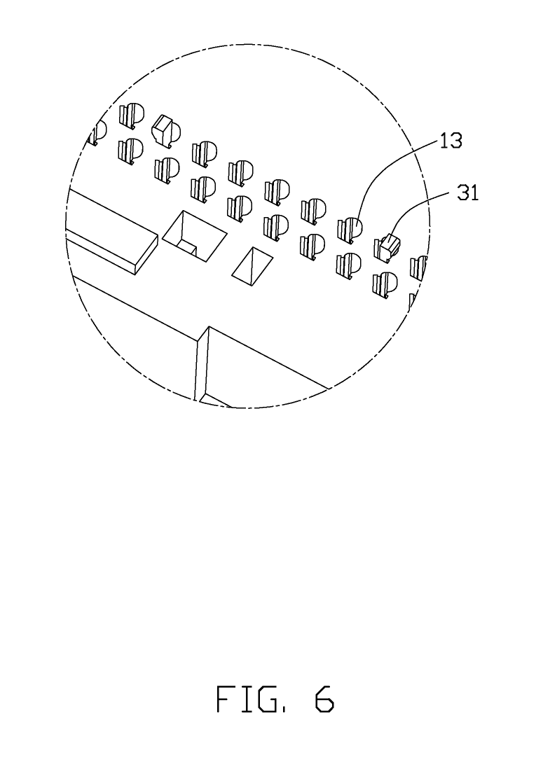

Referring to FIG. 1 and FIG. 2, the electrical connector 100 of the present disclosure provides two types of cap 3, 4. Two types of cap 3, 4 locate on the upper surface of the bottom wall 10 and cover partial receiving holes 13. Referring to FIG. 3 and FIG. 6, the first type of cap 3 comprises a base portion 30 and a pair of retention portions 31 extending downwardly from the base portion 30. The retention portion 31 receives in the receiving hole 13 and engages with the receiving hole 13. The base portion 30 abuts the upper surface of the bottom wall 10 and covers a plurality of receiving holes 13 to form a non-conductive portion. The non-conductive portion is an area having no contacts corresponding to an area of the CPU having no terminals thereon. The shape of the base portion 30 is determined by the shape of the non-conductive portion/area indeed needed. In this embodiment, the base portion 30 is T shaped. The receiving holes 13 under the base portion 30 are vacant receiving holes having no contacts 2 received therein. The base portion 30 has the same height with the supporting area 102 for supporting the IC package.

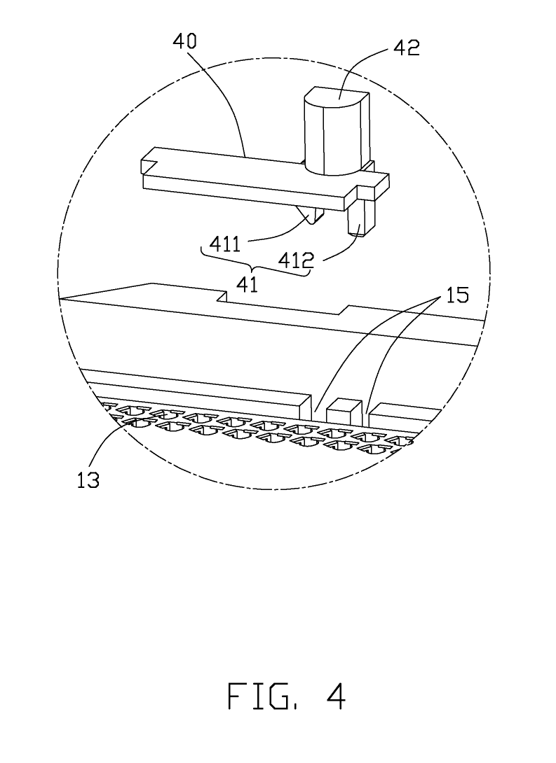

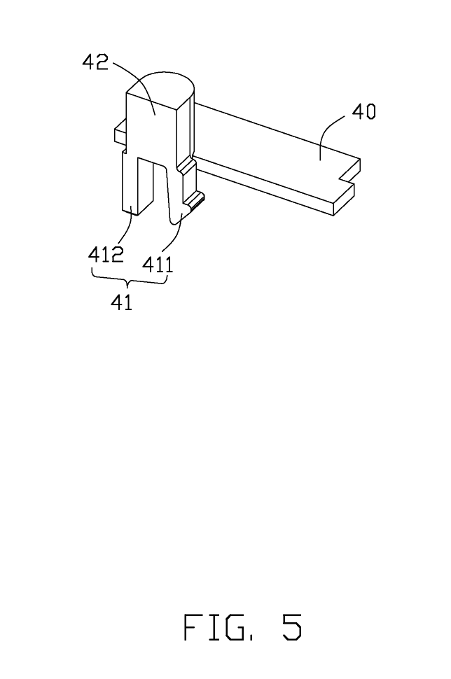

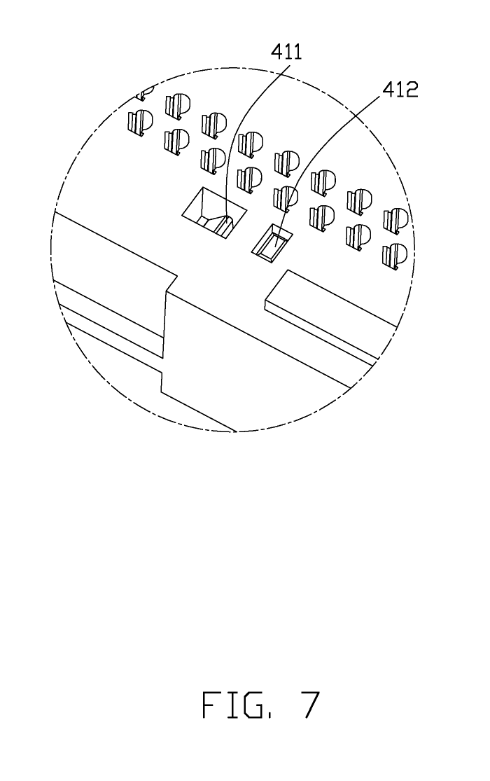

Referring to FIGS. 4, 5 and 7, the second type of cap 4 comprises a base portion 40, a position post 42 extending upwardly from the base portion 40 and a retention portion 41 extending downwardly from the position post 42. The base portion 40 abuts the upper surface of the bottom wall 10 and covers a plurality of receiving holes 13 to form a non-conductive portion. The base portion 40 has the same height with the supporting area 102 for supporting the IC package. The position post 42 is half-cylindrical and abuts the side wall 11 for matching with a half-cylindrical recess on the IC package. The retention portion 41 comprises a barb leg 411 and a straight leg 412. The insulating housing 1 comprises a retention hole 15 for receiving the retention portion 41. The barb leg 411 engages with the retention hole 15 for retaining the cap 4 thereon while the straight leg 412 is received in the retention hole 15 for guiding and positioning

In assembling, firstly, the cap 3, 4 is assembled on the insulating housing 1 to cover the receiving holes 13 in which the contacts 2 will not be set therein, i.e. the cap locates on the area of the insulating housing corresponding to the area of the CPU having no terminals thereon, then the contacts 2 are assembled in the remaining receiving holes 13, at last, the electrical connector 100 is soldered on the PCB for matching with the IC package.

The electrical connector 100 in accordance with a preferred embodiment of the present disclosure comprises a cap 3, 4 covering the receiving holes 13 in which the contacts 2 will not be set therein to form a non-conductive portion/area. Therefore, the electrical connector 100 can be used in different CPUs having different areas of no terminals by adjusting the shape and/or position of the cap.

While preferred embodiment in accordance with the present disclosure has been shown and described, equivalent modifications and changes known to persons skilled in the art according to the spirit of the present disclosure are considered within the scope of the present disclosure as defined in the appended claims.

What is claimed is:

1. An electrical connector for electrically connecting an IC package with a printed circuit board comprising:
an insulating housing comprising a bottom wall having an upper surface and a lower surface opposite to each other and a plurality of receiving holes running through the upper and lower surfaces;
a plurality of contacts received in the receiving holes, wherein the number of the contacts is less than the number of the receiving holes, partial receiving holes are vacant; and
at least one cap assembled on the upper surface of the bottom wall and covering at least one of the vacant receiving holes to form a non-conductive portion.

2. The electrical connector as claimed in claim 1, wherein the cap comprises a base portion covering on the receiving holes and a retention portion retaining in the insulating housing.

3. The electrical connector as claimed in claim 2, wherein the retention portion extends downwardly from the base portion and engages with the receiving holes.

4. The electrical connector as claimed in claim 2, wherein the cap comprises a position post extending upwardly from the base portion.

5. The electrical connector as claimed in claim 4, wherein the insulating housing comprises a side wall extending upwardly from the bottom wall, the position post abuts an inner surface of the side wall.

6. The electrical connector as claimed in claim 5, wherein the insulating housing comprises a retention hole, the retention portion of the cap extends downwardly from the position post and retains in the retention hole.

7. The electrical connector as claimed in claim 6, wherein the retention portion comprises a barb leg engaging with the retention hole and a straight leg for guiding and positioning.

8. The electrical connector as claimed in claim 2, wherein the bottom wall comprises a conductive area having the contacts retained therein and a supporting area having no contacts retained therein for supporting the IC package, and wherein the conductive area is lower than the supporting area.

9. The electrical connector as claimed in claim 8, wherein the base portion has the same height with the supporting area for supporting the IC package.

10. The electrical connector as claimed in claim 2, wherein the base portion is T shaped.

11. An electrical connector for electrically connecting a Central Processing Unit (CPU) with terminals thereon to a printed circuit board (PCB) comprising:
an insulating housing comprising a bottom wall and a plurality of receiving holes running through the bottom wall;
a plurality of contacts received in the receiving holes; and
a cap assembled on the bottom wall; wherein
the cap covers at least one of the receiving holes for forming a non-conductive area corresponding to an area of the CPU having no terminals thereon.

12. The electrical connector as claimed in claim 11, wherein the receiving holes covered by the cap have no contacts received therein.

13. The electrical connector as claimed in claim 11, wherein the cap comprises a base portion extending abutting the bottom wall and a retention portion extending downwardly and engaging with the bottom wall.

14. The electrical connector as claimed in claim 13, wherein the base portion is T shaped.

15. An electrical connector for use with an electronic package, comprising:
an insulative housing including a bottom wall and a plurality of side walls extending upwardly from a periphery of the bottom wall to commonly form a receiving cavity for receiving said electronic package therein;
a plurality of passageways extending through the bottom wall in a vertical direction and communicating with the receiving cavity via an upper face of said bottom wall, most of said passageways being equipped with corresponding contacts while less of said passageways being vacant without the contacts therein; and
a cover attached to the housing and shielding said vacant passageways around the upper face so as to form a non-conductive region compared with a conductive region formed by said most of passageways with therein said contacts for electrical operation.

16. The electrical connector as claimed in claim 15, wherein said bottom wall defines a supporting face above the upper face for upwardly supportable confrontation with said electronic package.

17. The electrical connector as claimed in claim 16, wherein said supporting face is located around the periphery of the bottom wall.

18. The electrical connector as claimed in claim 17, wherein said supporting face is higher than the upper face.

19. The electrical connector as claimed in claim 18, wherein the cover is dimensioned with a thickness to have thereof an upper surface coplanar with the supporting face when said cover is assembled upon the housing.

20. The electrical connector as claimed in claim 15, wherein the cover includes a retention device to assemble the cover to the housing, and said retention device is assembled into at least one of said vacant passageway rather than to other portions of the housing.
